(19) United States
(12) Patent Application Publication
(10) Pub. No.: US 2010/0040796 A1
(43) Pub. Date: Feb. 18, 2010

(54) Heat-dissipating structure and manufacturing method thereof

(76) Inventor: San-Teng Chueh, Lujhu Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/222,620

(22) Filed: Aug. 13, 2008

(51) Int. Cl. B05D 1/12; F28F 7/00; H05K 7/20

(52) U.S. Cl. 427/453; 427/446; 165/185; 361/704

(57) ABSTRACT

A manufacturing method for a heat-dissipating structure is disclosed. The manufacturing method comprises the following steps. Step 1 is preparing powders of materials with far infrared conversion. Step 2 is modifying surfaces of the powders and step 3 is thermal spraying the modified powders on a substrate for forming a heat-dissipating layer on the substrate. The heat-dissipating structure can contact with a heat source and the heat is dissipated by the radiation of far infrared. Moreover, the equivalent heat resistance between the substrate and air is reduced so that the heat dissipation efficiency is improved.

### BACKGROUND OF THE INVENTION

1. Field of the Invention

The present invention relates to a heat-dissipating structure and a manufacturing method thereof, and in particular to a heat-dissipating structure having a heat-dissipating layer with far infrared conversion and the manufacturing method thereof.

2. Description of Prior Art

The cooling of the electronic devices and the removal of heat generated by the electronic devices plays an important role in the electronic industry. For using the heat-dissipating means in the high integrate products and multi-function applications, various heat-dissipating structures with high heat-dissipating efficiency have developed

Heat-dissipating pieces are usually used for dissipating the heat from electronic devices, and such structures have a smaller heat resistance which is used for improving the efficiency of heat dissipation. Generally speaking, heat resistance is affected by the heat diffusion resistance inside the material and heat-transfer resistance at the boundary/interface between the material and air. Materials with high conductivity such as Cu and Al are used for heat dissipation because of the lower heat diffusion resistance. However, because the heat-transfer resistance at the interface can not be easily decreased, therefore the overall heat resistance can not be decreased. Therefore, the efficiency of heat dissipation is too low to meet the requirement of heat dissipation for the new generation electronic devices.

In tradition, a single material is formed into a heat-dissipating structure by molding, extrusion, or machining methods. The single material is formed into a particular shape with high surface areas and the gap between the structures can increase the heat dissipation through air flow, for example a common structure has a plurality of heat-dissipating fins for increasing the surface areas. Cu or Al material is usually used for manufacturing the single-material heat-dissipation structure; however, the single-material heat-dissipation structure has a significantly less efficient heat-dissipation rate when compared to heat-dissipation structure of composite materials.

Now, composite materials have been widely used for improving the dissipating efficiency of the heat-dissipating structure. For example, Cu and Al are combined for manufacturing heat sink with high conductivity of heat (the material characteristic of Cu) and low weight (the low density of Al). However, the problem of the interface resistance between different materials has not been solved.

Alternatively, an organic combiner is used for gluing the material with far infrared conversion on the metal plate, but the high heat resistance of the organic is still too high to improve the heat dissipation effect.

Therefore, in view of this, the inventor proposes the present invention to overcome the above problems based on his expert experience and deliberate research.

### SUMMARY OF THE INVENTION

The primary object of the present invention provides a manufacturing method for a heat-dissipating structure. The manufacturing method is applied for coating the powders with far infrared conversion on the substrate in order to form a heat-dissipating layer by thermal spraying method.

In order to achieve the above object, the present invention provides a manufacturing method for a heat-dissipating structure. The manufacturing method comprises the following steps. Step 1 is preparing powders of materials with far infrared conversion. Step 2 is modifying surfaces of the powders and step 3 is thermal spraying the modified powders on a substrate for forming a heat-dissipating layer on the substrate.

The present invention provides a heat-dissipating structure comprising a substrate and a heat-dissipating layer on the substrate. The heat-dissipating structure is disposed on a heat source for dissipating heat from the heat source. The substrate transmits heat form the heat source to the heat-dissipating layer and the heat-dissipating layer transfers and converts the heat into far infrared that radiates outward and dissipates.

In the present invention, the heat-dissipating layer is a thin and a uniform layer which can transfers and convert heat into far infrared, which is then radiated outward and dissipates. Therefore, heat is dissipation in two paths. One path is the heat conduction in solid and gas states (metal substrate, heat-dissipating layer and air) and the other path is the radiation of far infrared. Accordingly, heat dissipation efficiency is highly improved.

In order to better understand the characteristics and technical contents of the present invention, a detailed description thereof will be made with reference to the accompanying drawings. However, it should be understood that the drawings and the description are illustrative but not used to limit the scope of the present invention.

### BRIEF DESCRIPTION OF THE DRAWINGS

FIG. 1 is a flow chart showing the manufacturing method for a heat dissipating structure according to the present invention.

FIG. 2 is a schematic view showing the heat dissipating structure according to the present invention.

FIG. 3 is a schematic representation showing the heat dissipating structure being used for dissipating heat from the heat source by radiation of far infrared according to the present invention.

### DETAILED DESCRIPTION OF THE INVENTION

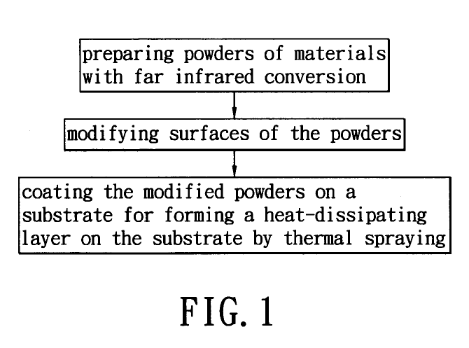

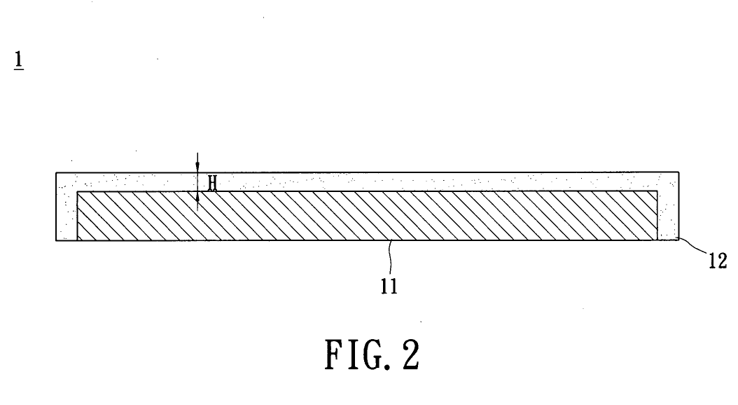

Please refer to FIGS. 1 and 2, wherein FIG. 1 shows a flow chart of the manufacturing method for a heat dissipating structure according to the present invention and FIG. 2 shows the heat dissipating structure according to the present invention. The manufacturing method is applied for coating the materials with far infrared conversion on a substrate 11 in order to form a heat-dissipating layer 12. The substrate 11 and the heat-dissipating layer 12 are constructed as a heat-dissipating structure 1 with high heat-dissipating efficiency. The manufacturing method for a heat-dissipating structure has the following steps.

Step 1 is preparing powders of materials with far infrared conversion. Generally speaking, materials with far infrared conversion are ores, but the compositions of the materials with far infrared conversion are too complex to control. However, most materials with far infrared conversion have rare earth elements with radiation property or heavy metals. On the other hand, inorganic materials also have far infrared characteristic (meaning capable of radiating far infrared), for example the tourmaline and volcanic rocks. Alternatively, the Moso bamboo or coconut shell can emit far infrared by converting heat after being baked to above 1000° C. Therefore, before step 1, the materials with far infrared conversion are analyzed. For example, the compositions and grain size of the materials with far infrared conversion are analyzed for preparing the powders with far infrared property and the powders have a predetermined emissivity value of the far infrared. In the embodiment, the powders are prepared by ceramic materials with far infrared characteristic. Specifically, the ceramic material has 10-15% of clay, 10-20% of phyllite and 40-50% of tourmaline. Furthermore, the ceramic material has 5-10% of orthoclase, 5-10% of albite, 5-10% of schreyerite (i.e. titanium and vanadium ores), 5-10% of cupric oxide (CuO), and 10% of organic material of DK 2001. The above-mentioned material is crushed, sieve-shook, mixed, granulated, baked, sintered, and so on for preparing the powder. However, the composition of the powders is not restricted to the above ratio. The prepared powders can be used for coating on the substrate 11. The substrate 11 is preferably a metal plate with high thermal conductivity and can be used for transmitting heat with high efficiency.

Step 2 is modifying surfaces of the powders. The characteristics of the surfaces of the powders, such as grain size and exterior surface, are modified so that the powders are coated on the substrate 11 with improved combination. Moreover, the modified powders can be coated on the substrate 11 using an efficient coating method. The crystalline phase (i.e. grain phase) of the powders is modified by step 2, for example the powders is processed by a heat treatment for improving the conductivity of the powders. Furthermore, the surface modification includes a coating step for coating a modifying shell on the powders in order to improve the fluidity of the powders. For example, an electro-plating step or a chemical plating step is applied for a shell with low melting temperature. The low melting point shell can be melted in lower temperature than the powders so that the molten shell can fill into the space between the powders. Accordingly, the fluidity of the powders is improved for optimizing the characteristic of powders.

Step 3 is coating the modified powders on the substrate 11 by a thermal spraying method for forming a heat-dissipating layer 12 on the substrate 11. The powders are coated on the substrate 11 to form a uniform coating layer (heat-dissipating layer 12), and the coating layer has the same emissivity value of the far infrared as the predetermined emissivity value of the far infrared of the powders. The heat-dissipating layer 12 directly combines with the substrate 11 without adhesive layer by the thermal spraying method so that the efficiency of heat-dissipating is improved.

The thermal spraying method may be achieved through the melting of the wire-type, stick-type, or powder-type material and then sending the molten or molten-like material onto a surface by a gas flow. The powders prepared in step 1 are melted by flame (i.e. flame spray, high velocity oxy-fuel (HVOF)) or electricity (arc spray, plasma spray) method, and the molten powders are transferred onto the substrate 11. When the molten powders arrive at the surface of the substrate 11, the powders are deposited and cooled layer by layer so as to form a uniform heat-dissipating layer 12. The heat-dissipating layer 12 can transmit and convert heat into radiation of far infrared but the heat conductivity of the heat-dissipating layer 12 is smaller than that of the substrate 11. Therefore, the thickness of the heat-dissipating 12 is limited to a predetermined length. Because of the smaller heat conductivity of the heat-dissipating layer 12, the thicker heat-dissipating layer 12 results in the low efficiency of heat-dissipating of the heat-dissipating structure 1. On the other hand, the thickness of the heat-dissipating layer 12 has a thinnest limit because the radiation of the far infrared is generated by the crystal structure of the coating layer. When the molten powders cool to form a very thin structure, the material hardly crystallizes. In other wards, the emissivity value of the far infrared is lower in the condition that the thickness of the heat-dissipating layer 12 is below the thinnest limit. In one embodiment, the heat-dissipating layer 12 has a uniform thickness H and the thickness H is less than 100 μm. With the thickness of the heat-dissipating layer 12, the heat-dissipating structure 1 has optimized heat conductivity and higher emissivity value of the far infrared.

Before the step of thermal coating, a pre-treatment step is applied for cleaning and roughening the surface of the substrate 11. The effect of the pre-treatment step is that cleaning the surface of the substrate 11 leads to the increase of contact area on the surface of substrate 11 with which the molten powders may contact and thereby improve the quality of the coating of thermal spraying. The cleaning step is used for removing the oxide-film, particles, oil, and so on. For example, a solvent is applied for removing the above matters to improve the combination of the coating layer and the substrate 11. Moreover, the surface of the substrate 11 is rough in order to increase the surface area of the substrate 11. Thus, the concave and the convex surfaces on the substrate 11 are used for increasing the combine strength of the heat-dissipating layer 12 and the substrate 11. In other words, the structural strength of the heat-dissipating layer 12 and the substrate 11 can be improved.

The primary condition of the thermal spraying depends on pressure and temperature, which are adjusted according to the kinds of the powders with far infrared conversion. For example, the angle of the gas flow is changed for sending powders with different melting points into different flame zones. Alternatively, electronic current or the gas composition, such as the ratio of helium and argon can be adjusted for improving the melting efficiency and the quality of coating layer.

The substrate 11 and the heat-dissipating layer 12 are constructed as a heat-dissipating structure 1 with high heat-dissipating efficiency. A heat-dissipating test is applied for measuring the heat-dissipating efficiency by contacting the heat-dissipating structure 1 to a heat source. Furthermore, a test for the grain phase (i.e. crystalline phase), thickness, emissivity, and adhesive strength of the heat-dissipating layer 12 is applied for determining the functions of the heat-dissipating structure 1.

The above manufacturing method can be applied with a continuous thermal spraying method to efficiently produce the heat-dissipating structure 1. Cooling air is induced into the continuous thermal spraying method to lower the processing temperature. Moreover, the thermal spraying method can easily be applied for substrates 11 in any size and any shape. Accordingly, the thermal spraying method is suitable for automatically and continuously producing the heat-dissipating structure 1.

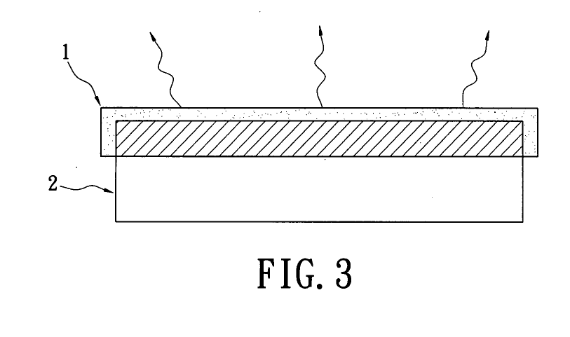

The present invention discloses a heat-dissipating structure 1 which includes a substrate 11 and a heat-dissipating layer 12 coated on the substrate 11 by a thermal spraying method. The heat-dissipating layer 12 is formed by powders with far infrared conversion. Please refer to FIG. 3, the heat-dissipating structure 1 is applied on a heat source 2, for example an electronic device, and the heat generated by the heat source 2 can be dissipated from the heat source 2 by the substrate 11 with high heat conductivity. The heat-dissipating layer 12 performs as a transferring means for transferring and converting the heat to a far infrared that radiates outward. The heat is transferred and converted into a radiation of far infrared (the arrow in FIG. 3) by the electronic transition of the crystalline of the heat-dissipating layer 12. The wavelength and the emissivity of the radiation are respectively 2-18 μm and 93%. The metal material could not absorb the radiation so that the radiation of far infrared is applied for dissipating heat efficiently. Therefore, the electronic device can be efficiently cooled.

To sum up, the present invention has the following advantages.

1. The present invention provides for an improved heat-dissipating efficiency. The heat is transferred and converted into far infrared which can radiate in longer distance than electromagnetic wave of infrared so that the heat is dissipated into the space for cooling the electronic devices. The effect of the far infrared is applied for the devices which generate heat when they are operating. The heat generated by the devices is transmitted to the heat-dissipating layer 12 with the emission of far infrared property by the substrate 11. Therefore, heat can be dissipated efficiently by the high heat conduction with the substrate 11 and by the radiation of far infrared of the heat-dissipating layer 12.

2. Moreover, the heat-dissipating layer 12 is formed on the substrate 11 by the thermal spraying method. The heat-dissipating layer 12 is a uniform structure so that the heat-dissipating efficiency is uniform, further more the uniformity of structure decreases heat resistance. The heat-transfer at the interface between the heat-dissipating layer 12 and the substrate 11 is increased because that the heat transfer between air and the substrate 11 has increased due to outward far infrared radiation. Therefore, the thickness and the crystalline of the heat-dissipating layer 12 are controlled optimally and the heat-dissipating structure with high heat-dissipating efficiency is manufactured.

Even though the present invention has been described with reference to the foregoing preferred embodiment, it shall be understood that the present invention is not limited to the details thereof. Various equivalent variations and modifications may occur to those skilled in this art in view of the teachings of the present invention. Thus, all such variations and equivalent modifications are also embraced within the scope of the present invention as defined in the appended claims.

What is claimed is:

1. A manufacturing method for a heat-dissipating structure, comprising:
step 1: preparing powders of materials with far infrared conversion;
step 2: modifying surfaces of the powders; and
step 3: thermal spraying the modified powders on a substrate for forming a heat-dissipating layer on the substrate.

2. The manufacturing method for a heat-dissipating structure according to claim 1, wherein the powders having a predetermined emissivity value of the far infrared is used in step 1.

3. The manufacturing method for a heat-dissipating structure according to claim 2, wherein the powders are prepared by ceramic materials with characteristic of capable of radiating far infrared.

4. The manufacturing method for a heat-dissipating structure according to claim 3, wherein the ceramic materials includes clay, phyllite, and tourmaline.

5. The manufacturing method for a heat-dissipating structure according to claim 4, wherein the ceramic materials further includes orthoclase, albite, schreyerite, and cupric oxide (CuO).

6. The manufacturing method for a heat-dissipating structure according to claim 3, wherein step 2 is applied for modifying grain size, grain phase, and exterior surface of the powders, and for improving the fluidity of the powders.

7. The manufacturing method for a heat-dissipating structure according to claim 6, wherein the substrate is directly coated by the modified powders by thermal spraying in step 3.

8. The manufacturing method for a heat-dissipating structure according to claim 7, wherein the heat-dissipating layer has the same emissivity value of the far infrared as the predetermined emissivity value of the far infrared of the powders.

9. The manufacturing method for a heat-dissipating structure according to claim 8, wherein the heat-dissipating layer has a predetermined thickness.

10. The manufacturing method for a heat-dissipating structure according to claim 9, wherein the predetermined thickness is less than 100 μm.

11. A heat-dissipating structure manufactured by the method of claim 1, comprising:
a substrate and a heat-dissipating layer on the substrate, wherein the heat-dissipating structure is disposed on a heat source, the substrate transmits heat form the heat source to the heat-dissipating layer, and the heat-dissipating layer transfers and converts the heat into far infrared for radiation.
